(19) United States
(12) Patent Application Publication
(10) Pub. No.: US 2024/0379885 A1
(43) Pub. Date: Nov. 14, 2024

(54) RAY DETECTOR, MANUFACTURING METHOD THEREOF, AND ELECTRONIC DEVICE

(71) Applicant: BOE TECHNOLOGY GROUP CO., LTD., Beijing (CN)

(72) Inventors: Hao WU, Beijing (CN); Feng GUAN, Beijing (CN); Jianhua DU, Beijing (CN); Yang LV, Beijing (CN); Rui YAN, Beijing (CN); Meng ZHAO, Beijing (CN); Chaolu WANG, Beijing (CN)

(21) Appl. No.: 18/032,582

(22) PCT Filed: May 30, 2022
(86) PCT No.: PCT/CN2022/095895

§ 371 Date: Apr. 19, 2023

(51) Int. Cl. H01L 31/0392; H01L 27/146; H01L 29/786

(52) U.S. Cl. CPC H01L 31/0392; H01L 27/14692; H01L 29/7869

(57) ABSTRACT

The present disclosure provides a ray detector, a method for manufacturing a ray detector, and an electronic device. The method includes: forming a buffer layer on a first surface of a substrate, wherein the first surface of the substrate includes a first region and a second region; forming a shared layer on a surface of the buffer layer distal to the substrate; processing a portion of the shared layer in the first region to obtain an active layer of a thin film transistor; and processing a portion of the shared layer in the second region to obtain an absorption layer of a photodiode.

### CROSS-REFERENCE TO RELATED APPLICATIONS

This is a National Phase Application filed under 35 U.S.C. 371 as a national stage of PCT/CN2022/095895 filed on May 30, 2022, the entire content of which is incorporated herein by reference.

### TECHNICAL FIELD

The present disclosure relates to the field of semiconductor technology, and in particular, to a ray detector, a method for manufacturing a ray detector, and an electronic device.

### BACKGROUND

The X-ray detection technology is widely applied to the fields of industrial nondestructive detection, container scanning, circuit board inspection, medical treatment, security protection, industry, and the like, and has a wide application prospect. The traditional X-Ray imaging technology belongs to analog signal imaging, and has a low resolution and a poor image quality. The digital radiography (DR) technology of X-ray appearing in the late 90s of the 20th century adopts an X-ray photodetector to directly convert an X-ray image into a digital image, and has been a hot spot of current researches because the converted digital image is clear, has a high resolution, and is easy to be stored and transmitted.

A ray detector may include a scintillator, an image sensor, a control unit, a signal processing unit, and a communication unit. The scintillator absorbs an X-ray and converts the X-ray into visible light. The image sensor is formed by a pixel array consisting of photodiodes and thin film transistors (TFTs), and converts the visible light generated by the scintillator into an electric signal under the drive of a control circuit. The signal processing unit amplifies the electric signal, converts the electric signal into a digital signal through an analog-to-digital converter, and performs correction and compensation processing on the digital signal to form an image.

### SUMMARY

The present disclosure is to provide a ray detector, a method for manufacturing a ray detector, and an electronic device.

In a first aspect of the present disclosure, there is provided a method for manufacturing a ray detector, the method including:
forming a buffer layer on a first surface of a substrate, wherein the first surface of the substrate comprises a first region and a second region;
forming a shared layer on a surface of the buffer layer distal to the substrate;
processing a portion of the shared layer in the first region to obtain an active layer of a thin film transistor; and processing a portion of the shared layer in the second region to obtain an absorption layer of a photodiode.

In an embodiment, prior to the forming the shared layer on the surface of the buffer layer distal to the substrate, the method further comprises:
patterning the buffer layer to obtain a guiding trench;
forming an inducing layer on the surface of the buffer layer distal to the substrate;
patterning the inducing layer to form another inducing layer; and processing the another inducing layer to obtain inducing particles in the guiding trench.

In an embodiment, a material of the shared layer comprises amorphous silicon (a-Si), and the active layer comprises a nanowire; and
the processing the portion of the shared layer in the first region to obtain the active layer of the thin film transistor comprises:
annealing the shared layer to cause silicon atoms in the shared layer to be precipitated along the guiding trench under an induction of the inducing particles to form a silicon nanowire.

In an embodiment, after the annealing the shared layer to cause the silicon atoms in the shared layer to be precipitated along the guiding trench under the induction of the inducing particles to form the silicon nanowire, the method further comprises:
removing the inducing particles except the nanowire by an etchant; and
removing a residue of the shared layer in the first region by a plasma enhanced chemical vapor deposition process and by using hydrogen plasma etching.

In an embodiment, the processing the portion of the shared layer in the second region to obtain the absorption layer of the photodiode comprises:
processing the portion of the shared layer in the second region by using a laser annealing process to transform the portion of the shared layer in the second region into p-type polycrystalline silicon;
doping a first doped region with a first dopant and doping a second doped region with a second dopant, wherein the first doped region comprises at least one convex portion and at least one concave portion, the second doped region comprises at least one convex portion and at least one concave portion, each convex portion of the first doped region is embedded in a corresponding concave portion of the second doped region, and each convex portion of the second doped region is embedded in a corresponding concave portion of the first doped region.

In an embodiment, after the doping the first doped region with the first dopant and doping the second doped region with the second dopant, the method further comprises:
forming a sacrificial layer on a surface of the portion of the buffer layer in the first region distal to the substrate;
forming a transition layer on a surface of the sacrificial layer distal to the substrate; and
patterning the transition layer and the sacrificial layer by a single patterning process to form a first transition electrode and a second transition electrode in the transition layer.

In an embodiment, after the patterning the transition layer and the sacrificial layer by a single patterning process to form the first transition electrode and the second transition electrode in the transition layer, the method further comprises:
forming a first electrode layer which covers the transition layer and the absorption layer; and
patterning the first electrode layer, to form a first transistor electrode and a second transistor electrode in the first region and a first diode electrode and a second diode electrode in the second region, wherein the first transistor electrode is stacked on the first transition electrode, the second transistor electrode is stacked on the second transition electrode, the first diode electrode is stacked on the first doped region, and the second diode electrode is stacked on the second doped region.

In an embodiment, after the patterning the first electrode layer, the method further comprises:
forming an insulating layer which covers an exposed surface of the buffer layer, the active layer, the first electrode layer and the absorption layer;
forming a third transistor electrode on a surface, which is distal to the substrate, of a portion of the insulating layer in the first region;
forming a dielectric layer which covers an exposed surface of the insulating layer and the third transistor electrode, and forming a first conductive pillar and a lead, which penetrate through the dielectric layer and the insulating layer along a thickness direction of the dielectric layer and the insulating layer, and are respectively electrically connected to the first diode electrode and the second diode electrode; and
forming a planarization layer which covers an exposed surface of the dielectric layer and the lead.

In a second aspect, embodiments of the present disclosure provide a ray detector, comprising:
a substrate and a buffer layer on a first surface of the substrate, wherein the first surface of the substrate comprises a first region and a second region; and
an active layer of a thin film transistor on a portion of the buffer layer in the first region, an absorption layer of a photodiode on a surface, which is distal to the substrate, of a portion of the buffer layer in the second region;
wherein the active layer of the thin film transistor and the absorption layer of the photodiode are in a same layer.

In an embodiment, the absorption layer of the photodiode comprises a first doped region and a second doped region, the first doped region comprises at least one convex portion and at least one concave portion, the second doped region comprises at least one convex portion and at least one concave portion, each convex portion of the first doped region is embedded in a corresponding concave portion of the second doped region, and each convex portion of the second doped region is embedded in a corresponding concave portion of the first doped region.

In an embodiment, the ray detector further includes a first electrode layer on a surface of the absorption layer distal to the substrate, wherein the first electrode layer comprises a first diode electrode and a second diode electrode of the photodiode, the first diode electrode is stacked on the first doped region, and the second diode electrode is stacked on the second doped region.

In an embodiment, the first doped region and the second doped region are doped with different dopants, respectively.

In an embodiment, the active layer comprises a nanowire; and on a side of the active layer distal to the substrate there are a transition layer and a first electrode layer stacked sequentially, the transition layer comprises a first transition electrode and a second transition electrode, the first electrode layer comprises a first transistor electrode and a second transistor electrode, the first transition electrode is sandwiched between the first transistor electrode and a source region of the nanowire, and the second transition electrode is sandwiched between the second transistor electrode and a drain region of the nanowire.

In an embodiment, the ray detector further includes a sacrificial layer between the transition layer and the active layer.

In an embodiment, the ray detector further includes an insulating layer and a third transistor electrode, wherein the insulating layer covers an exposed surface of the buffer layer, the active layer, the first electrode layer and the absorption layer; and the third transistor electrode is on a surface, which is distal to the substrate, of a portion of the insulating layer in the first region.

In an embodiment, the ray detector further includes a dielectric layer covering an exposed surface of the insulating layer and the third transistor electrode.

In an embodiment, the ray detector further includes an anode layer, and the anode layer comprises a first lead electrode and a second lead electrode.

In an embodiment, the ray detector further includes leads, which penetrate through the dielectric layer and the insulating layer along a thickness direction of the dielectric layer and the insulating layer, and are respectively electrically connected to the first diode electrode and the second diode electrode. The leads are electrically connected to the first lead electrode and the second lead electrode, respectively.

In an embodiment, the ray detector further includes a formed planarization layer covering an exposed surface of the dielectric layer and the anode layer.

In an embodiment, the substrate comprises one of a glass-based substrate and a silicon-based substrate.

In a third aspect, embodiments of the present disclosure provide an electronic device including the ray detector according to any one of the foregoing embodiments of the second aspect.

### BRIEF DESCRIPTION OF THE DRAWINGS

FIG. 1 is a schematic diagram of growing a nanowire by using an in-plane solid-liquid-solid (IP-SLS) technology;

FIG. 2 is a flowchart of a method for manufacturing a ray detector according to an embodiment of the present disclosure;

FIG. 3 is a cross-sectional view of a ray detector according to an embodiment of the present disclosure;

FIG. 4 is a schematic diagram showing a structure formed after step S401 in the method according to an embodiment of the present disclosure is performed;

FIG. 5 is a cross-sectional view taken along a line A-A′ shown in FIG. 4, according to an embodiment of the present disclosure;

FIG. 6 is a schematic diagram showing a structure formed after step S402 in the method according to an embodiment of the present disclosure is performed;

FIG. 7 is a cross-sectional view taken along the line A-A′ shown in FIG. 6, according to an embodiment of the present disclosure;

FIG. 8 is a schematic diagram showing a structure formed after step S403 in the method according to an embodiment of the present disclosure is performed;

FIG. 9 is a cross-sectional view taken along the line A-A′ shown in FIG. 8, according to an embodiment of the present disclosure;

FIG. 10 is a schematic diagram showing a structure formed after step S404 in the method according to an embodiment of the present disclosure is performed;

FIG. 11 is a cross-sectional view taken along the line A-A′ shown in FIG. 10, according to an embodiment of the present disclosure;

FIG. 12 is a schematic diagram showing a structure formed after step S405 in the method according to an embodiment of the present disclosure is performed;

FIG. 13 is a cross-sectional view taken along the line A-A′ shown in FIG. 12, according to an embodiment of the present disclosure;

FIG. 14 is a schematic diagram showing a structure formed after step S406 in the method according to an embodiment of the present disclosure is performed;

FIG. 15 is a cross-sectional view taken along the line A-A′ shown in FIG. 14, according to an embodiment of the present disclosure;

FIG. 16 is a schematic diagram showing a structure formed after step S407 in the method according to an embodiment of the present disclosure is performed;

FIG. 17 is a cross-sectional view taken along the line A-A′ shown in FIG. 16, according to an embodiment of the present disclosure;

FIG. 18 is a schematic diagram showing a structure formed after step S408 in the method according to an embodiment of the present disclosure is performed;

FIG. 19 is a cross-sectional view taken along the line A-A′ shown in FIG. 18, according to an embodiment of the present disclosure;

FIG. 20 is a schematic diagram showing a structure formed after step S409 in the method according to an embodiment of the present disclosure is performed;

FIG. 21 is a cross-sectional view taken along the line A-A′ shown in FIG. 20, according to an embodiment of the present disclosure;

FIG. 22 is a schematic diagram showing a structure formed after step S410 in the method according to an embodiment of the present disclosure is performed;

FIG. 23 is a cross-sectional view taken along the line A-A′ shown in FIG. 22, according to an embodiment of the present disclosure;

FIG. 24 is a schematic diagram showing a structure formed after step S411 in the method according to an embodiment of the present disclosure is performed;

FIG. 25 is a cross-sectional view taken along the line A-A′ shown in FIG. 24, according to an embodiment of the present disclosure;

FIG. 26 is a schematic diagram showing a structure formed after step S412 in the method according to an embodiment of the present disclosure is performed; and

FIG. 27 is a cross-sectional view taken along the line A-A′ shown in FIG. 26, according to an embodiment of the present disclosure.

The reference numerals in the figures are described as follows:
1—substrate, 2—insulating layer, 3—nanoparticle, 4—precursor layer, 5—alloy droplet, 6—seed crystal, 7—nanowire, 8—buffer layer, 11—first region, 12—second region, 13—active layer, 14—absorption layer, 15—first doped region, 16—second doped region, 17—convex portion, 18—concave portion, 19—convex portion, 20—concave portion, 21—first electrode layer, 22—first diode electrode, 23—second diode electrode, 24—nanowire, 25—first transition electrode, 26—second transition electrode, 27—first transistor electrode, 28—second transistor electrode, 29—third transistor electrode, 30—dielectric layer, 31—first lead electrode, 32—first conductive pillar, 33—planarization layer, 34—guiding trench, 35—inducing layer, 36—shared layer, 37—indium inducing particle, 38—silicon nanowire, 41—sacrificial layer, 42—through hole, 43—photoresist.

### DETAILED DESCRIPTION OF EMBODIMENTS

To help one of ordinary in the art better understand technical solutions of the present disclosure, the present disclosure will be further described in detail below with reference to the accompanying drawings and exemplary embodiments.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like does not denote a limitation of quantity, but rather denotes the presence of at least one element. The term of “comprising”, “including”, or the like, means that the element or item preceding the term contains the element or item listed after the term and its equivalent, but does not exclude the presence of other elements or items. The terms “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

Embodiments of the present disclosure provide a method for manufacturing a ray detector, and the method mainly adopts a micro lens array (MLA) regionalized laser annealing technology. That is, a laser beam from a laser source is divided into a laser spot array through a micro lens array technology, and high-position precision laser annealing is selectively performed on amorphous silicon (a-Si) in a specified region, to form P-type polycrystalline silicon (P-Si), thereby improving a utilization efficiency of the laser.

The method for manufacturing a ray detector according to an embodiment of the present disclosure further adopts an in-plane solid-liquid-solid (IP-SLS) growth technology, which is a method for growing nanowires through metal catalysis. A silicon-based nanowire grown by this technology has the characteristic of mono-like crystal, and is grown at a temperature lower than 400° C., such that this technology has a high compatibility with an existing display panel production line.

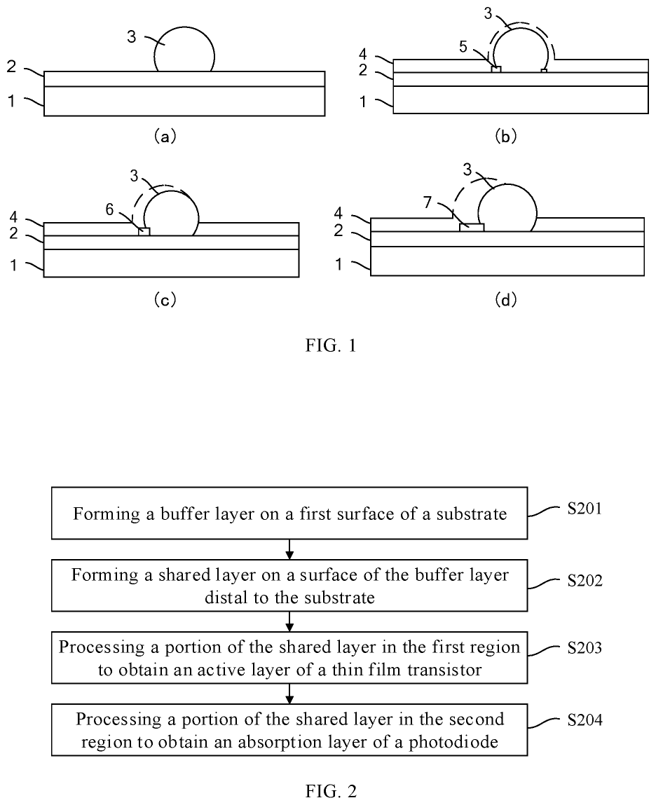

FIG. 1 is a schematic diagram of growing a nanowire by using the IP-SLS technology. As shown in FIG. 1, the principle of growing a nanowire includes the following steps S11 to S14.

Step S11 includes forming an insulating layer 2 on a surface of a substrate 1, forming a catalytic layer on a surface of the insulating layer 2 distal to the substrate 1, and performing in-situ treatment on a metal particle to form a nanoparticle 3, as shown in part (a) of FIG. 1.

Step S12 includes depositing a precursor layer 4 on the surface of the substrate 1, and then heating the substrate 1 to form alloy droplets 5, such as indium alloy droplets, at a three-phase interface, as shown in part (b) of FIG. 1.

Step S13 includes transmitting predetermined atoms absorbed at an interface of each of the alloy droplets 5 to an interface between the alloy droplet and a nanowire, to precipitate (or separate out) a seed crystal 6, as shown in part (c) of FIG. 1.

Step S14 includes causing the seed crystal 6 with the largest diameter to tilt (or warp) the alloy droplets 5 to move in an opposite direction under the drive of the Gibbs free energy, to form a new absorption interface, thereby obtaining a nanowire 7 finally, as shown in part (d) of FIG. 1.

According to an embodiment of the present disclosure, a ray detector including a thin film transistor and a photodiode is manufactured by the method for manufacturing a ray detector, thereby reducing a manufacturing cost of the ray detector.

FIG. 2 is a flowchart of a method for manufacturing a ray detector according to an embodiment of the present disclosure. As shown in FIG. 2, the method includes the following S201 to S204.

Step S201 includes forming a buffer layer on a first surface of a substrate.

The substrate includes, but is not limited to, a glass substrate and a silicon substrate, and a material of the substrate is not limited in the present disclosure. The substrate includes the first surface and a second surface which are opposite to each other, and each of the first surface and the second surface may bear a thin film transistor and a photodiode thereon. For convenience of description, the embodiments of the present disclosure are described by taking an example in which the first surface bears a thin film transistor and a photodiode thereon.

In an embodiment of the present disclosure, the first surface of the substrate includes a first region and a second region, and the first region and the second region do not overlap each other. The first region is used for arranging a thin film transistor, and the second region is used for arranging a photodiode. Alternatively, the first region is used for disposing a photodiode, and the second region is used for disposing a thin film transistor. That is, a thin film transistor and a photodiode are disposed in different regions of the substrate, respectively.

The buffer layer may be made of a silicide such as silicon nitride (SiNx) or silicon oxide (SiOx), or an organic material such as polyimide or acrylic.

In some embodiments, the buffer layer may be formed by a deposition process, such as a physical vapor deposition process or a chemical vapor deposition process. A thickness of the buffer layer is not limited in the embodiments of the present disclosure, and for example, the thickness of the buffer layer may be 4,000 angstroms.

Step S202 includes forming a shared layer on a surface of the buffer layer distal to the substrate.

A material of the shared layer may be amorphous silicon (a-Si), or may be another suitable material. A thickness of the shared layer in the present embodiment is 200 angstroms to 600 angstroms.

In some embodiments, the shared layer is formed by a deposition process, and the shared layer completely covers the buffer layer. That is, the shared layer is deposited in both the first region and the second region, and is deposited in both the first region and the second region by a single process.

Step S203 includes processing a portion of the shared layer in the first region to obtain an active layer of a thin film transistor.

In an embodiment of the present disclosure, the first region and the second region are processed, respectively, to realize different functions.

In some embodiments, the portion of the shared layer in the first region is processed, for example, annealed, to cause atoms required in the shared layer to be precipitated to form the active layer.

Step S204 includes processing a portion of the shared layer in the second region to obtain an absorption layer of a photodiode.

In some embodiments, the portion of the shared layer in the second region is processed, for example, is subjected to annealing and ion implantation, to obtain the absorption layer of the photodiode.

In some embodiments, prior to the step S202 of forming the shared layer on the surface of the buffer layer distal to the substrate, the method further includes steps of:
patterning the buffer layer to obtain a guiding trench; forming an inducing layer on a surface of the buffer layer distal to the substrate; patterning the inducing layer to form a final inducing layer; and processing the final inducing layer to obtain inducing particles within the guiding trench.

In some embodiments, the buffer layer is patterned by processes of coating, exposing, and developing to obtain the guiding trench in the buffer layer. A depth of the guiding trench may be the same as a thickness of the buffer layer, i.e. the first surface of the substrate serves as the bottom of the guiding trench. Alternatively, the depth of the guiding trench is less than the thickness of the buffer layer, i.e. the bottom of the guiding trench is a portion of the buffer layer.

In some embodiments, a plurality of guiding trenches spaced apart from each other are obtained in the buffer layer, and a distance between any adjacent two of the guiding trenches may be set as required, which is not limited in an embodiment of the present disclosure.

In some embodiments, the inducing layer may be formed by a deposition process. The inducing layer may be made of a material including, but not limited to, indium tin oxide (ITO), and the inducing layer has a thickness of 100 angstroms to 400 angstroms. Further, the inducing layer is patterned through processes of coating, exposing and developing to form a strip-shaped inducing layer, and a width of the strip-shaped inducing layer covers all the guiding trenches in a direction in which the guiding trenches are arranged.

In some embodiments, the inducing particles are obtained in the guiding trench by a plasma enhanced chemical vapor deposition (PECVD) process and a reduction (or deoxidization) treatment performed on indium tin oxide by using a hydrogen plasma. A diameter of each of the inducing particles corresponds to (e.g., is equal to) a width of the guiding trench. In the case where the inducing layer is made of ITO, the inducing particles are silicon inducing particles.

In some embodiments, the active layer includes a nanowire, and in a case where a material of the shared layer includes amorphous silicon (α-Si), the step S203 of processing the portion of the shared layer in the first region to obtain the active layer of the thin film transistor may include a step of:
annealing the shared layer to precipitate (or separate out) silicon atoms in the shared layer along the guiding trench under the induction of the inducing particles, to form the silicon nanowire.

In an example, annealing treatment is carried out on amorphous silicon (α-Si) at the temperature of 350° C. to 400° C., to cause the silicon atoms in the shared layer to be precipitated along the guiding trench under the induction of the inducing particles, thereby forming the silicon nanowire. In an embodiment of the present disclosure, a line width of the silicon nanowire is limited by the width of the guiding trench, and a height of the silicon nanowire may be lower than a height of the surface of the buffer layer distal to the substrate, or may be equal to the height of the surface of the buffer layer distal to the substrate, or may be higher than the height of the surface of the buffer layer distal to the substrate. For convenience of description and illustration, the following embodiments are described by taking the example in which the height of the silicon nanowire is higher than the height of the surface of the buffer layer distal to the substrate.

In some embodiments, after the step of annealing the shared layer to precipitate (or separate out) silicon atoms in the shared layer along the guiding trench under the induction of the inducing particles to form the silicon nanowire, the method includes steps of:
removing the inducing particles outside the nanowire through an etchant, and removing the residues of the shared layer in the first region through a plasma enhanced chemical vapor deposition process and hydrogen plasma etching.

Exemplarily, an etchant for ITO is used for removing excess indium particles, which are inducing particles formed outside the guiding trench during the generation of the inducing particles. The residue of the shared layer, which is the residual substance after the silicon element is precipitated (or separated out) after the annealing treatment, is removed by the plasma enhanced chemical vapor deposition process and hydrogen plasma etching.

It should be noted that after the residue of the portion of the shared layer in the first region is removed, the portion of the shared layer in the second region still remains. In addition, when the portion of the shared layer in the first region is annealed at 350° C. to 400° C., the crystal form of the α-Si of the portion of the shared layer in the second region will not be changed due to the low annealing temperature.

In some embodiments, the step S204 of processing the portion of the shared layer in the second region to obtain the absorption layer of the photodiode includes steps of:
processing the portion of the shared layer in the second region by using a laser annealing process to enable the portion of the shared layer in the second region to be changed into p-type polycrystalline silicon; doping a first doped region with a first dopant, and doping a second doped region with a second dopant; where the first doped region includes at least one convex portion and at least one concave portion which are arranged parallel to a plane where the substrate is located, the second doped region includes at least one convex portion and a concave portion which are arranged parallel to the plane where the substrate is located, each convex portion of the first doped region is embedded in the concave portion of the second doped region, and each convex portion of the second doped region is embedded in a corresponding concave portion of the first doped region.

In some embodiments, an MLA regionalized laser annealing technology is used for annealing the portion of the shared layer in the second region at 550°° C. to 600° C., to cause the crystal form of the portion of the shared layer in the second region to be converted into p-Si. Then, the first doped region of the second region is doped with the first dopant through processes of coating photoresist, exposing, developing and implanting, and then the coated photoresist is removed. Similarly, the second doped region of the second region is doped with the second dopant through processes of coating photoresist, exposing, developing and implanting, and then the coated photoresist is removed.

In some embodiments, the first doped region includes at least one convex portion and at least one concave portion, the second doped region includes at least one convex portion and a concave portion, each convex portion of the first doped region is embedded in the concave portion of the second doped region, and each convex portion of the second doped region is embedded in a corresponding concave portion of the first doped region, thereby an interdigital photodiode is formed in the second region, i.e., an interdigital doped region is formed in the portion of the shared layer in the second region along a lateral direction (i.e., along a plane where the shared layer is located), which can make the incident light perpendicular to a direction of an electric field, thereby enhancing the regulation capability of the electric field, increasing a light absorption area, making a thickness of the absorption layer smaller, and thus reducing a volume of the ray detector.

In some embodiments, the first doped region is doped with the first dopant, and the second doped region is doped with the second dopant. Alternatively, the first doped region is doped with the second dopant, and the second doped region is doped with the first dopant.

In some embodiments, the first dopant includes a P+ type dopant, and the second dopant includes an N+type dopant, where the P+ type dopant includes, but is not limited to, pentavalent elements such as phosphorus and arsenic, or boron fluoride (BF3); the N+ type dopant include, but is not limited to, trivalent elements such as boron and gallium, or boron hydride (PH3).

In some embodiments, after doping the first doped region with the first dopant and doping the second doped region with the second dopant, the method further includes steps of:
forming a sacrificial layer on a surface of a portion of the buffer layer in the first region distal to the substrate; forming a transition layer on a surface of the sacrificial layer distal to the substrate; and patterning the transition layer and the sacrificial layer through a single patterning process, to form a first transition electrode and a second transition electrode in the transition layer.

The sacrificial layer is made of a material including a-Si, and has a thickness of 300 angstroms to 500 angstroms. A method for forming the sacrificial layer is not limited in an embodiment of the present disclosure, and for example, the sacrificial layer may be formed by a deposition process. The transition layer may be made of N+ amorphous silicon, and may have a thickness of 500 Å to 1,000 Å. A method for forming the transition layer is not limited in an embodiment of the present disclosure, and for example, the transition layer may be formed by a deposition process. Since the sacrificial layer is arranged between the transition layer and the active layer, when the sacrificial layer is patterned, the nanowire can be prevented from being damaged. In this way, the mobility of the nanowire is ensured, and meanwhile, a leakage current of the thin film transistor is reduced.

In some embodiments, the transition layer and the sacrificial layer are patterned by a single patterning process, to form the first transition electrode and the second transition electrode in the transition layer, such that the first transition electrode and the second transition electrode are beneficial to enabling the electrodes and the nanowire to form an ohmic contact, thereby reducing a contact resistance, and avoiding the large resistance phenomenon of a silicon nanowire thin film transistor.

In some embodiments, after the transition layer and the sacrificial layer are patterned by a single patterning process to form the first transition electrode and the second transition electrode in the transition layer, the method further includes steps of:
forming a first electrode layer, where the first electrode layer covers the transition layer and the absorption layer; patterning the first electrode layer to form a first transistor electrode and a second transistor electrode in the first region, and to form a first diode electrode and a second diode electrode in the second region, where the first transistor electrode is stacked on the first transition electrode, the second transistor electrode is stacked on the second transition electrode, the first diode electrode is stacked on the first doped region, and the second diode electrode is stacked on the second doped region.

A material of the first electrode layer includes at least one of conductive metals such as molybdenum, copper, aluminum, etc., and a thickness of the first electrode layer is 2,000 angstroms or more, for example, is 2,200 angstroms. The method for forming the first electrode layer is not limited in an embodiment of the present disclosure, and for example, the first electrode layer is formed by a physical vapor deposition process.

In some embodiments, a portion of the first electrode layer in the first region is patterned through processes of coating, exposing, and developing to obtain the first transistor electrode and the second transistor electrode. Here, the first transistor electrode may be a drain electrode of the thin film transistor, and the second transistor electrode may be a source electrode of the thin film transistor; alternatively, the first transistor electrode may be the source electrode of the thin film transistor, and the second transistor electrode may be the drain electrode of the thin film transistor.

In some embodiments, a portion of the first electrode layer in the second region is patterned by processes of coating, exposing and developing, to form the first diode electrode and the second diode electrode, where the first diode electrode is stacked on the first doped region, and the second diode electrode is stacked on the second doped region.

It should be noted that the patterning of the first region and the patterning of the second region may be completed by a single coating, exposing and developing process, i.e., the first transistor electrode, the second transistor electrode, the first diode electrode and the second diode electrode are obtained by the single coating, exposing and developing process.

In some embodiments, after patterning the first electrode layer, the method further includes steps of:

forming an insulating layer, where the insulating layer covers the exposed surface of the buffer layer, the active layer, the first electrode layer and the absorption layer;
forming a third transistor electrode on a surface of a portion of the insulating layer in the first region distal to the substrate;
forming a dielectric layer, where the dielectric layer covers the exposed surface of the insulating layer and the third transistor electrode, and forming a lead which penetrates through the dielectric layer and the insulating layer along a thickness of the dielectric layer and the insulating layer and is electrically connected to the first diode electrode;
forming an anode layer, and patterning the anode layer to form a first lead electrode and a second lead electrode at one end of a conductive pillar (i.e., respectively conductive pillar) distal to the substrate, where the first lead electrode and the second lead electrode are electrically connected to corresponding leads, respectively; and
forming a planarization layer, where the planarization layer covers the exposed surface of the dielectric layer and the anode layer.

The insulating layer may be made of silicide such as silicon nitride (SiNx) or silicon oxide (SiOx), or an organic material such as polyimide and acrylic.

In some embodiments, the insulating layer may be formed by a deposition process, such as a physical vapor deposition process or a chemical vapor deposition process. A thickness of the insulating layer is not limited in an embodiment of the present disclosure, and for example, the thickness of the insulating layer is 3,000 angstroms.

In some embodiments, a conductive layer is formed on a surface of a portion of the insulating layer in the first region distal to the substrate, and the third transistor electrode is formed in the conductive layer through processes of coating, exposing, developing and etching. A material of the conductive layer may be a conductive metal, such as molybdenum or copper. The conductive layer has a thickness of 500angstroms or 2,200 angstroms.

In some embodiments, the third transistor electrode may be a gate electrode of the thin film transistor, and the first transistor electrode, the second transistor electrode, and the third transistor electrode form the thin film transistor.

In some embodiments, a material of the dielectric layer includes, but is not limited to, silicon oxide (SiOx) or silicon nitride (SiNx). The dielectric layer covers the exposed surface of portions of the insulating layer respectively in the first region and the second region and the third transistor electrode. The dielectric layer may have a thickness of 800 angstroms or 400 angstroms. A method for forming the dielectric layer is not limited in an embodiment of the present disclosure, and for example, the dielectric layer may be formed by a deposition process or another process.

Through holes are formed in the dielectric layer and the insulating layer along the thickness direction of the dielectric layer and the insulating layer through processes of coating, exposing, developing and etching, and positions of the through holes correspond to the first diode electrode and/or the second diode electrode, respectively. A conductive metal is filled in each through hole by a deposition process, thereby forming a conductive pillar in each through hole, where a first conductive pillar is electrically connected to the first diode electrode, and a second lead is electrically connected to the second diode electrode.

The anode layer is formed on the surface of the dielectric layer distal to the substrate by a deposition process, and is patterned to form a first lead electrode and a second lead electrode, where the first lead electrode and the second lead electrode are electrically connected to corresponding leads, respectively.

The anode layer may be made of any one or more of molybdenum, copper, aluminum, and other conductive metals, and may have a thickness of 1,000 angstroms or more. The thickness and the manufacturing process of the anode layer are not limited in an embodiment of the present disclosure.

The planarization layer is formed on the surface of the anode layer distal to the substrate, and the material, thickness and manufacturing process of the planarization layer are not limited in an embodiment of the present disclosure. For example, the material of the planarization layer includes an organic resin, the thickness of the planarization layer is 2,000 angstroms, and a method for forming the planarization layer may be coating.

In the method for manufacturing a ray detector according to any one of the foregoing embodiments, the active layer of the thin film transistor and the absorption layer of the photodiode are obtained after processing of the shared layer formed by a same process, thereby achieving the sharing of a film layer, and reducing the manufacturing cost of the ray detector.

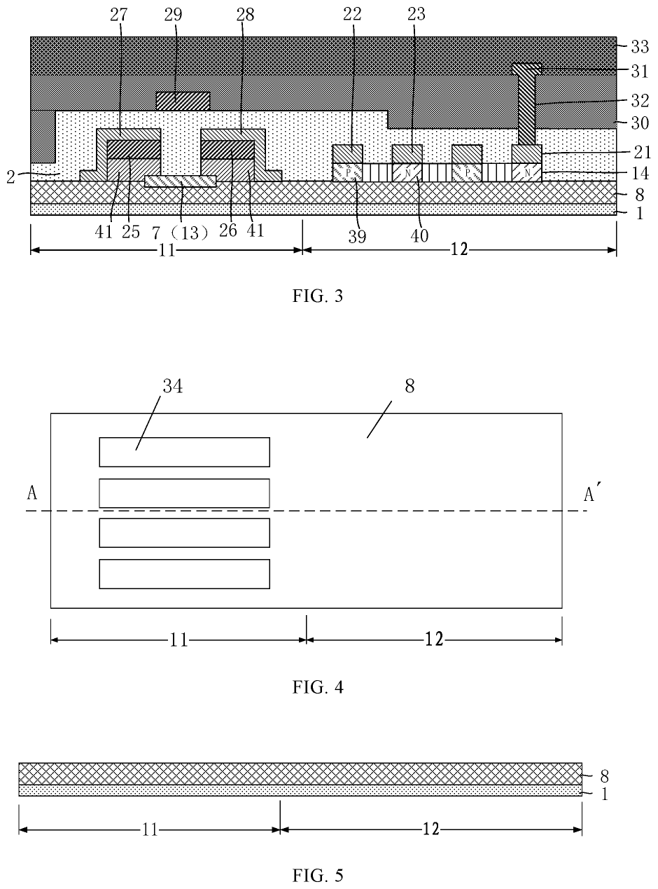

Embodiments of the present disclosure further provide a ray detector. FIG. 3 is a cross-sectional view of a ray detector according to an embodiment of the present disclosure. As shown in FIG. 3, the ray detector includes:
a substrate 1, and a buffer layer 8 disposed on a first surface of the substrate 1; where the first surface of the substrate 1 includes a first region 11 and a second region 12.

The ray detector further includes an active layer 13 of a thin film transistor arranged on a portion of the buffer layer 8 in the first region 11, and an absorption layer 14 of a photodiode stacked on a surface, which is distal to the substrate 1, of a portion of the buffer layer 8 in the second region 12;
where the active layer 13 of the thin film transistor and the absorption layer 14 of the photodiode are disposed in a same layer, i.e., the active layer 13 of the thin film transistor and the absorption layer 14 of the photodiode have a same distance from the first surface of the substrate.

In some embodiments, the substrate includes, but is not limited to, a glass substrate and a silicon substrate, and a material of the substrate is not limited in the present disclosure. The substrate includes the first surface and the second surface which are opposite to each other, and each of the first surface and the second surface may bear thereon an array substrate. For convenience of description, the embodiments of the present disclosure are described by taking an example in which the first surface bears thereon an array substrate.

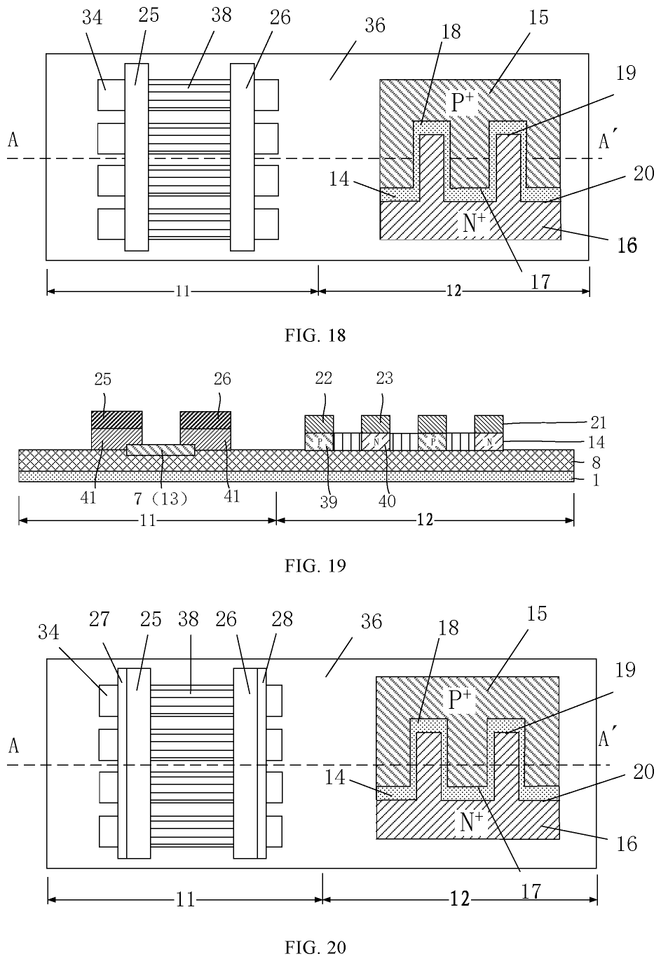

In some embodiments, referring to FIGS. 3 and 18, the absorption layer 14 of the photodiode includes a first doped region 15 and a second doped region 16. The first doped region 15 includes at least one convex portion 17 and at least one concave portion 18 disposed parallel to a plane where the substrate 1 is located. The second doped region 16 includes at least one convex portion 19 and at least one concave portion 20 disposed parallel to the plane where the substrate 1 is located. Further, each convex portion 17 of the first doped region 15 is embedded in a corresponding concave portion 20 of the second doped region 16, each convex portion 19 of the second doped region 16 is embedded in a corresponding concave portion 18 of the first doped region 15, and the first doped region 15 and the second doped region 16 are not in contact with each other. The first doped region 15 and the second doped region 16 form an interdigital structure in a plane where the absorption layer 14 is located, such that a direction of an electric field is parallel to the plane where the absorption layer is located.

In the present embodiment, the absorption layer of the photodiode is configured to have the interdigital structure, such that the direction of the electric field is parallel to the plane where the absorption layer is located, and an incident light is perpendicular to the plane where the absorption layer is located. That is, the incident light is perpendicular to the direction of the electric field, such that the regulation capability of the electric field can be enhanced, the light absorption area can be increased; moreover, the thickness of the absorption layer can be reduced, i.e., the thickness of the absorption layer is reduced under a same photosensitive condition.

In some embodiments, a first electrode layer 21 is disposed on a surface of the absorption layer 14 distal to the substrate 1, and is provided therein with a first diode electrode 22 and a second diode electrode 23 of the photodiode, where the first diode electrode 22 is stacked on the first doped region 15, and the second diode electrode 23 is stacked on the second doped region 16.

In some embodiments, the first doped region 15 and the second doped region 16 are doped with different types of dopants (i.e., impurities), respectively.

In some embodiments, the first doped region is doped with a first dopant, and the second doped region is doped with a second dopant. Alternatively, the first doped region is doped with the second dopant, and the second doped region is doped with the first dopant.

In some embodiments, the first dopant includes the P+type dopant, and the second dopant includes the N+type dopant, where the P+type dopant includes, but is not limited to, pentavalent elements such as phosphorus, arsenic, or the like, the N+type dopant includes, but is not limited to, trivalent elements such as boron, gallium, or the like.

In some embodiments, the active layer 13 includes a nanowire 24

A transition layer and a first electrode layer 21 are sequentially stacked on a side of the active layer 13 distal to the substrate 1. The transition layer includes a first transition electrode 25 and a second transition electrode 26, and the first electrode layer 21 includes a first transistor electrode 27 and a second transistor electrode 28. Further, the first transition electrode 25 is sandwiched between the first transistor electrode 27 and a source region of the nanowire 24, and the second transition electrode 26 is sandwiched between the second transistor electrode 28 and a drain region of the nanowire 24.

In the present embodiment, the first transition electrode and the second transition electrode are beneficial to forming ohmic contact between an electrode and the nanowire, such that the contact resistance is reduced, and the large resistance of the silicon nanowire thin film transistor is avoided.

In some embodiments, a material of the transition layer may be N+ amorphous silicon, and a thickness of the transition layer is 500 Å to 1,000 Å.

In some embodiments, a sacrificial layer is disposed between the transition layer and the active layer 13. The sacrificial layer is made of a material including α-Si, and has a thickness of 300 angstroms to 500 angstroms.

In the present embodiment, since the sacrificial layer is arranged between the transition layer and the active layer, when the sacrificial layer is patterned, the nanowire can be prevented from being damaged. As such, the mobility of the nanowire is ensured, and a leakage current of the thin film transistor is reduced.

In some embodiments, the ray detector further includes an insulating layer 2 and a third transistor electrode 29. The insulating layer 2 covers the exposed surface of the buffer layer 8, the active layer 13, the first electrode layer 21, and the absorption layer 14. The third transistor electrode 29 is arranged on a surface, which is distal to the substrate 1, of a portion of the insulating layer 2 in the first region 11.

In some embodiments, a material of the insulating layer may be a silicide such as silicon nitride (SiNx) or silicon oxide (SiOx), or an organic material such as polyimide or acrylic. A thickness of the insulating layer 2 is not limited in an embodiment of the present disclosure, and may be 3,000 angstroms, for example.

In some embodiments, the ray detector further includes a dielectric layer 30, which covers the exposed surface of the insulating layer 2 and the third transistor electrode 29.

In some embodiments, the ray detector further includes an anode layer, which includes a first lead electrode 31 and a second lead electrode (not shown in the figures), and a first lead 32 and a second lead (not shown in the figures) which penetrate through the dielectric layer 30 and the insulating layer 2 along the thickness direction of the dielectric layer 30 and the insulating layer 2 and are respectively electrically connected to the first diode electrode 22 and the second diode electrode 23.

An end of the first lead 32 and an end of the second lead which are distal to the substrate 1 are electrically connected to the first lead electrode 31 and the second lead electrode, respectively.

In some embodiments, the ray detector further includes the formed planarization layer 33, which covers the exposed surface of the dielectric layer 30 and the anode layer.

In the ray detector according to the present embodiment, the buffer layer is arranged on the first surface of the substrate, the active layer of the thin film transistor is embedded in the portion of the buffer layer in the first region, and the absorption layer of the photodiode is stacked on the surface, which is distal to the substrate, of the portion of the buffer layer in the second region. Further, the active layer of the thin film transistor and the absorption layer of the photodiode are arranged in a same layer, thereby achieving the sharing of a film layer, and reducing the manufacturing cost of the ray detector.

For better understanding of the embodiments of the present disclosure, a ray detector and a method, which includes the following steps S401 to S412, for manufacturing the ray detector according to embodiments of the present disclosure will be further described below with reference to FIGS. 4 to 27.

Step S401 includes forming a buffer layer on a first surface of a glass substrate, and patterning the buffer layer to obtain a guiding trench in the buffer layer, as shown in FIGS. 4 and 5.

In step S401, the substrate 1 is the glass substrate and the buffer layer 8 is made of SiOx. A buffer layer having a thickness of 4,000 angstroms is formed on the first surface of the substrate 1 through a deposition process, and then patterned through processes of coating, exposing, and developing, thereby obtaining a plurality of guiding trenches 34 in the buffer layer, where the plurality of guiding trenches 34 are spaced apart from each other.

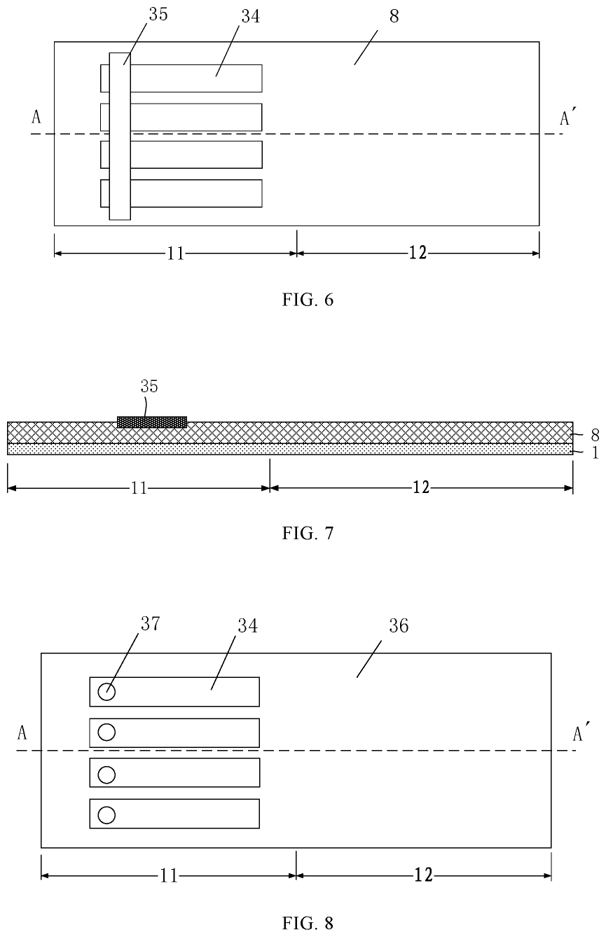

Step S402 includes forming an inducing layer on a surface of the buffer layer distal to the substrate, and patterning the inducing layer to obtain a strip-shaped inducing layer, as shown in FIGS. 6 and 7.

In step S402, the inducing layer 35 is made of indium tin oxide (ITO). An inducing layer 35 with a thickness of 300 angstroms is formed on a surface, which is distal to the substrate 1, of a portion of the buffer layer 8 in the first region 11 through a deposition process, and then is patterned through processes of coating, exposing and developing to obtain the strip-shaped inducing layer.

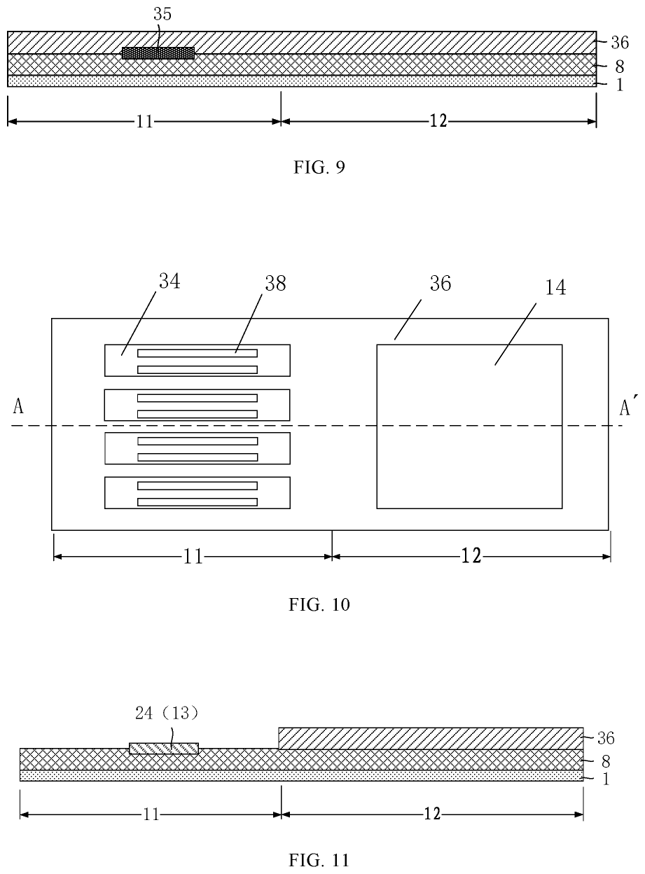

Step S403 includes processing the inducing layer to obtain inducing particles, and forming a shared layer, as shown in FIGS. 8 and 9.

In step S403, a material of the shared layer 36 is a-Si. Indium inducing particles 37 are obtained in the guiding trench by performing a reduction (or deoxidization) process on indium tin oxide using a plasma enhanced chemical vapor deposition (PECVD) process and hydrogen plasma. Then, the shared layer 36 is formed on the surface of the buffer layer 8 distal to the substrate through a deposition process, and the shared layer 36 covers the surfaces, which are distal to the substrate, of the portions of the buffer layer 8 in the first region and the second region.

Step S404 includes processing the portion of the shared layer in the first region to form nanowires, as shown in FIGS. 10 and 11.

In step $404, the portion of the shared layer 36 in the first region is processed at a temperature of 390° C., to cause silicon atoms in the shared layer 36 to be precipitated along the guiding trench 34 under the induction of the indium inducing particles 37, thereby forming silicon nanowires 38.

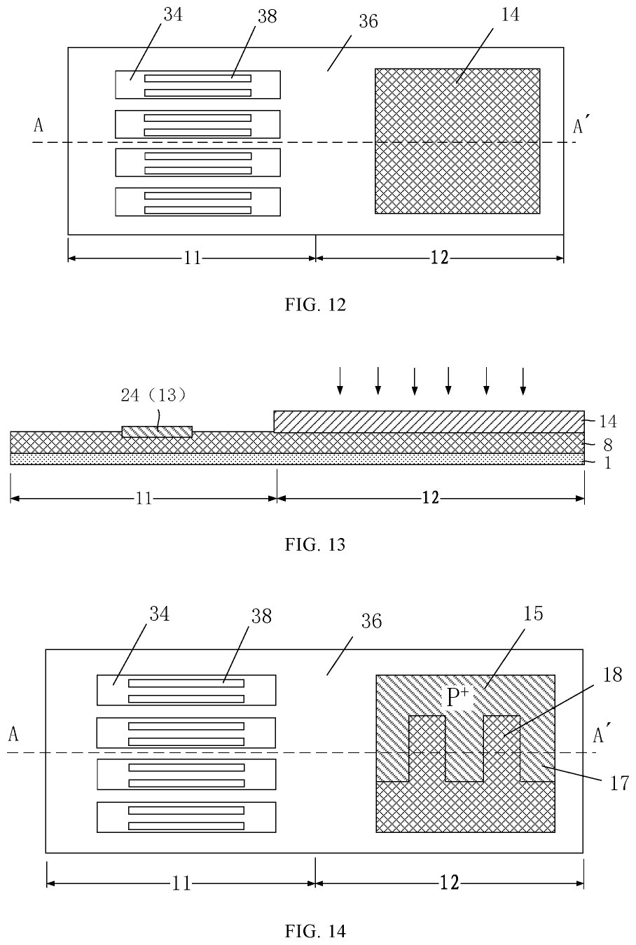

Step S405 includes processing the portion of the shared layer in the second region to obtain p-type polysilicon, as shown in FIGS. 12 and 13.

In step S405, the portion of the shared layer 36 in the second region 12 is annealed at 550° C. to 600° C. by using the MLA regionalized laser annealing technology, to transform the portion of the shared layer 36 in the second region 12 into p-Si.

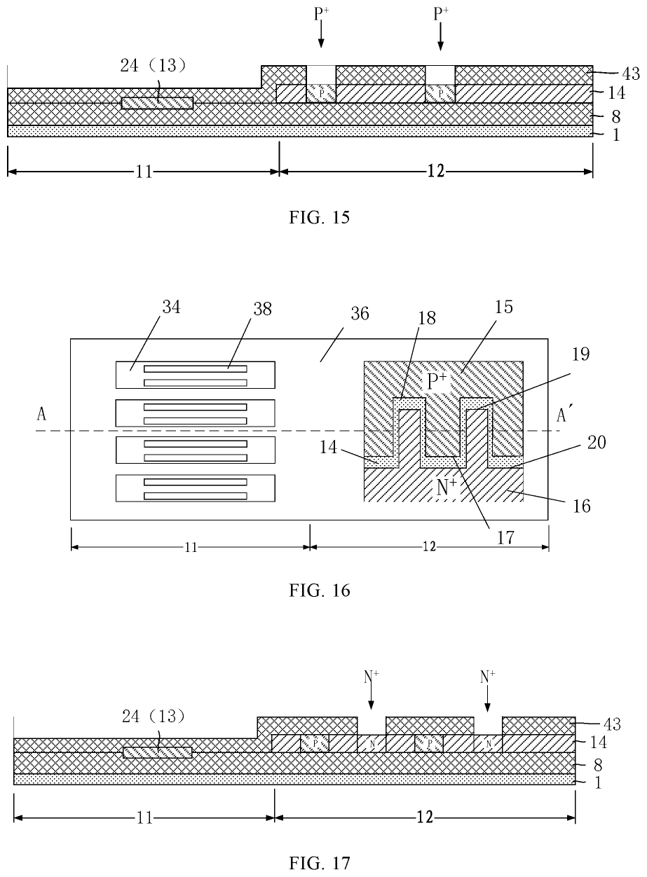

Step S406 includes doping the first doped region with a first dopant, as shown in FIGS. 14 and FIG. 15.

In step S406, a region except the first doped region 15 is masked by a photoresist 43 to expose the first doped region 15 through processes of coating, exposing and developing, then the first doped region 15 is doped with boron fluoride (BF3) through a doping process, and the photoresist is removed. When the photoresist is removed, care is taken not to damage the silicon nanowires of the active region.

Step S407 includes doping the second doped region with a second dopant, as shown in FIGS. 16 and 17.

In step S407, the second dopant is boron hydride (PH3). A region except the second doped region 16 is masked by a photoresist to expose the second doped region 16 through processes of coating, exposing and developing, then the second doped region 16 is doped with boron hydride (PH3) through a doping process, and the photoresist is removed. When the photoresist is removed, care is taken not to damage the silicon nanowires of the active region.

An interdigital photodiode is formed in the absorption layer 14 by steps S406 and S407.

Step S408 includes forming a sacrificial layer and a transition layer sequentially, and patterning the transition layer, as shown in FIGS. 18 and 19.

In step S408, a material of the sacrificial layer 41 includes α-Si, and a material of the transition layer includes N+ α-Si. A sacrificial layer 41 is deposited on the surface of the active layer 13 distal to the substrate 1, through a deposition process, the transition layer is deposited on the surface of the sacrificial layer 41 distal to the substrate 1 through a deposition process, and then the transition layer is patterned through processes of coating, exposing and developing to obtain a first transition electrode 25 and a second transition electrode 26. Since the sacrificial layer is arranged between the transition layer and the active layer, the silicon nanowires can be prevented from being damaged when the transition layer is etched, and meanwhile, a leakage current of the thin film transistor is reduced. The transition layer can form ohmic contact with an electrode layer, thereby reducing a contact resistance, and avoiding the phenomenon of large resistance of the thin film transistor.

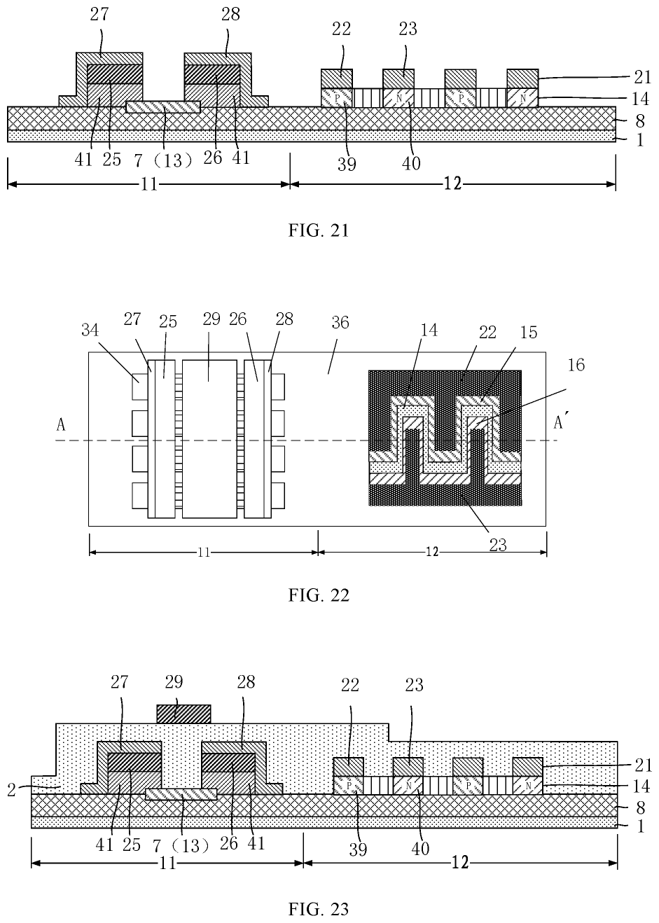

Step S409 includes forming a first electrode layer, and patterning the first electrode layer, to obtain a first transistor electrode and a second transistor electrode in the first region, and a first diode electrode 22 and a second diode electrode 23 in the second region, as shown in FIGS. 20 and 21.

In step S409, a material of the first electrode layer 21 is copper. The first electrode layer 21 with a thickness of 2,200 angstroms is formed by a deposition process, and then the first electrode layer 21 is patterned by processes of coating, exposing and developing, to obtain a first transistor electrode 27 and a second transistor electrode 28 in a portion of the first electrode layer 21 in the first region 11, where the first transistor electrode 27 and the second transistor electrode 28 may serve as a source electrode and a drain electrode of a thin film transistor, respectively, and to obtain the first diode electrode 22 and the second diode electrode 23 in a portion of the first electrode layer 21 in the second region 12.

Step S410 includes forming an insulating layer and a second electrode layer, where the insulating layer covers exposed surfaces of the buffer layer, the active layer, the first electrode layer, and the absorption layer, and obtaining a third transistor electrode in the second electrode layer through a patterning process, as shown in FIGS. 22 and 23.

In step S410, the insulating layer 2 is formed by a deposition process, where a material of the insulating layer 2 may be silicon oxide (SiOx), a thickness of the insulating layer 2 is 4,000 angstroms, and the insulating layer 2 covers exposed surfaces of the buffer layer 8, the active layer 13, the first electrode layer 21, and the absorption layer 14 to protect the buffer layer 8, the active layer 13, the first electrode layer 21, and the absorption layer 14 and isolate the first electrode layer 21. The second electrode layer is deposited by a deposition process on the surface of the insulating layer 2 distal to the substrate 1, and patterned by processes of coating, exposing and developing, to obtain a third transistor electrode 29 in the second electrode layer.

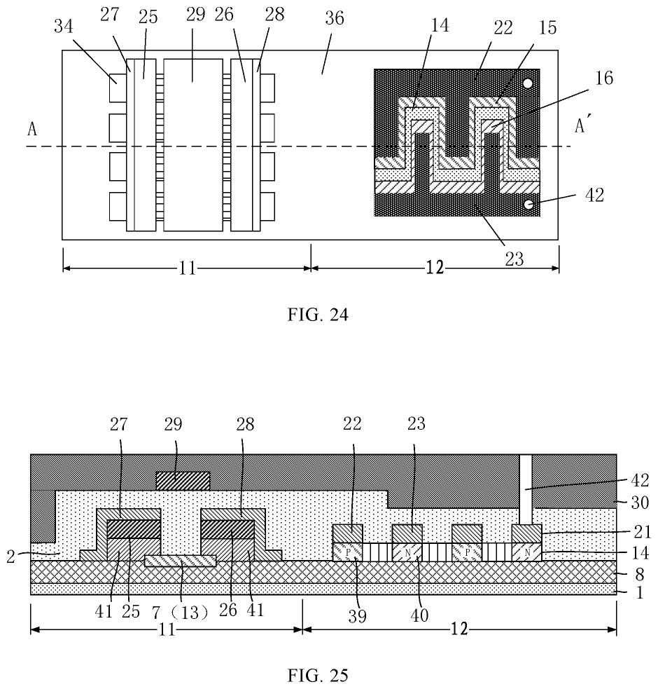

Step S411 includes forming a dielectric layer, and forming through holes penetrating through the dielectric layer and the insulating layer along a thickness direction of the dielectric layer and the insulating layer, as shown in FIGS. 24 and 25.

In step S411, a dielectric layer 30 with a thickness of 800 angstroms is formed by depositing silicon oxide (SiOx) on the surface of the insulating layer 2 distal to the substrate through a deposition process, where the dielectric layer 30 covers the exposed surfaces of the portions of the insulating layer in the first region and the second region and the third transistor electrode 29. A through hole 42 is formed in the dielectric layer, where the through hole 42 penetrates through the dielectric layer 30 and the insulating layer 2, to expose a surface of the first diode electrode 22 or the second diode electrode 23 distal to the substrate 1.

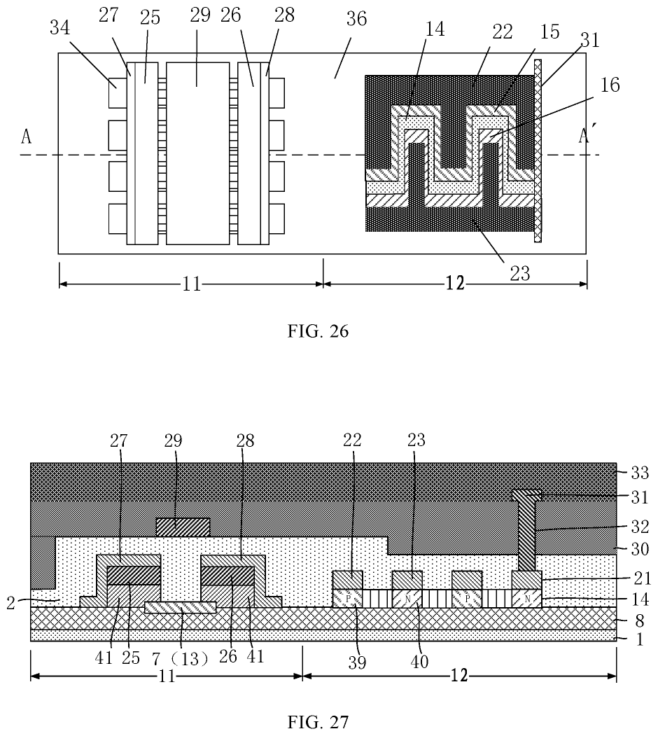

Step S412 includes forming an anode layer, filling the through hole with a material electrically conductive with the anode layer, and forming a planarization layer on the surface of the anode layer distal to the substrate 1, as shown in FIGS. 26 and 27.

In step S412, copper is deposited on the surface of the dielectric layer 30 by a deposition process to obtain an anode layer having a thickness of 1,000 angstroms, and each through hole 42 is filled with copper to form the first lead 32 and the second lead in the respective through holes 42. Then, the anode layer is patterned by processes of coating, exposing and developing, and the first lead electrode 31 is formed in the anode layer. Finally, a planarization layer 33 with a thickness of 3,000 angstroms is formed on the surface of the anode layer distal to the substrate 1, through a deposition process, where the planarization layer 33 covers the exposed surfaces of the anode layer and the dielectric layer 30, thereby protecting not only the anode layer and the dielectric layer 30, but also other functional layers.

It should be understood that the above embodiments are merely exemplary embodiments employed to illustrate the principles of the present disclosure, and the present disclosure is not limited thereto. It will be apparent to one of ordinary in the art that various changes and modifications may be made therein without departing from the spirit and scope of the present disclosure, and such changes and modifications are to be considered within the scope of the present disclosure.

1. A method for manufacturing a ray detector, the method comprising:
forming a buffer layer on a first surface of a substrate, wherein the first surface of the substrate comprises a first region and a second region;
forming a shared layer on a surface of the buffer layer distal to the substrate;
processing a portion of the shared layer in the first region to obtain an active layer of a thin film transistor; and
processing a portion of the shared layer in the second region to obtain an absorption layer of a photodiode.

2. The method according to claim 1, wherein prior to the forming the shared layer on the surface of the buffer layer distal to the substrate, the method further comprises:
patterning the buffer layer to obtain a guiding trench;
forming an inducing layer on the surface of the buffer layer distal to the substrate;
patterning the inducing layer to form another inducing layer; and
processing the another inducing layer to obtain inducing particles in the guiding trench.

3. The method according to claim 2, wherein a material of the shared layer comprises amorphous silicon, and the active layer comprises a nanowire; and
the processing the portion of the shared layer in the first region to obtain the active layer of the thin film transistor comprises:
annealing the shared layer to cause silicon atoms in the shared layer to be precipitated along the guiding trench under an induction of the inducing particles to form a silicon nanowire.

4. The method according to claim 3, wherein after the annealing the shared layer to cause the silicon atoms in the shared layer to be precipitated along the guiding trench under the induction of the inducing particles to form the silicon nanowire, the method further comprises:
removing the inducing particles except the nanowire by an etchant; and
removing a residue of the shared layer in the first region by a plasma enhanced chemical vapor deposition process and by using hydrogen plasma etching.

5. The method according to claim 3, wherein the processing the portion of the shared layer in the second region to obtain the absorption layer of the photodiode comprises:
processing the portion of the shared layer in the second region by using a laser annealing process to transform the portion of the shared layer in the second region into p-type polycrystalline silicon;
doping a first doped region with a first dopant and doping a second doped region with a second dopant, wherein the first doped region comprises at least one convex portion and at least one concave portion which are arranged parallel to a plane where the substrate is located, the second doped region comprises at least one convex portion and at least one concave portion which are arranged parallel to the plane where the substrate is located, each convex portion of the first doped region is embedded in a corresponding concave portion of the second doped region, and each convex portion of the second doped region is embedded in a corresponding concave portion of the first doped region.

6. The method according to claim 5, wherein after the doping the first doped region with the first dopant and doping the second doped region with the second dopant, the method further comprises:
forming a sacrificial layer on a surface of the portion of the buffer layer in the first region distal to the substrate;
forming a transition layer on a surface of the sacrificial layer distal to the substrate; and
patterning the transition layer and the sacrificial layer by a single patterning process to form a first transition electrode and a second transition electrode in the transition layer.

7. The method according to claim 6, wherein after the patterning the transition layer and the sacrificial layer by a single patterning process to form the first transition electrode and the second transition electrode in the transition layer, the method further comprises:
forming a first electrode layer which covers the transition layer and the absorption layer; and
patterning the first electrode layer, to form a first transistor electrode and a second transistor electrode in the first region and a first diode electrode and a second diode electrode in the second region, wherein the first transistor electrode is stacked on the first transition electrode, the second transistor electrode is stacked on the second transition electrode, the first diode electrode is stacked on the first doped region, and the second diode electrode is stacked on the second doped region.

8. The method according to claim 7, wherein after the patterning the first electrode layer, the method further comprises:
forming an insulating layer which covers an exposed surface of the buffer layer, the active layer, the first electrode layer and the absorption layer;
forming a third transistor electrode on a surface, which is distal to the substrate, of a portion of the insulating layer in the first region;
forming a dielectric layer which covers an exposed surface of the insulating layer and the third transistor electrode, and forming a first conductive pillar and a lead, which penetrate through the dielectric layer and the insulating layer along a thickness direction of the dielectric layer and the insulating layer, and are respectively electrically connected to the first diode electrode and the second diode electrode; and
forming a planarization layer which covers an exposed surface of the dielectric layer and the lead.

9. A ray detector, comprising:
a substrate and a buffer layer on a first surface of the substrate, wherein the first surface of the substrate comprises a first region and a second region; and
an active layer of a thin film transistor on a portion of the buffer layer in the first region, an absorption layer of a photodiode on a surface, which is distal to the substrate, of a portion of the buffer layer in the second region;
wherein the active layer of the thin film transistor and the absorption layer of the photodiode are in a same layer.

10. The ray detector according to claim 9, wherein the absorption layer of the photodiode comprises a first doped region and a second doped region, the first doped region comprises at least one convex portion and at least one concave portion arranged parallel to a plane where the substrate is located, the second doped region comprises at least one convex portion and at least one concave portion arranged parallel to the plane where the substrate is located, each convex portion of the first doped region is embedded in a corresponding concave portion of the second doped region, and each convex portion of the second doped region is embedded in a corresponding concave portion of the first doped region.

11. The ray detector according to claim 10, further comprising a first electrode layer on a surface of the absorption layer distal to the substrate, wherein the first electrode layer comprises a first diode electrode and a second diode electrode of the photodiode, the first diode electrode is stacked on the first doped region, and the second diode electrode is stacked on the second doped region.

12. The ray detector according to claim 11, wherein the first doped region and the second doped region are doped with different dopants, respectively.

13. The ray detector according to claim 11, wherein the active layer comprises a nanowire; and
on a side of the active layer distal to the substrate there are a transition layer and a first electrode layer stacked sequentially, the transition layer comprises a first transition electrode and a second transition electrode, the first electrode layer comprises a first transistor electrode and a second transistor electrode, the first transition electrode is sandwiched between the first transistor electrode and a source region of the nanowire, and the second transition electrode is sandwiched between the second transistor electrode and a drain region of the nanowire.

14. The ray detector according to claim 13, further comprising a sacrificial layer between the transition layer and the active layer.

15. The ray detector according to claim 14, further comprising an insulating layer and a third transistor electrode, wherein the insulating layer covers an exposed surface of the buffer layer, the active layer, the first electrode layer and the absorption layer; and
the third transistor electrode is on a surface, which is distal to the substrate, of a portion of the insulating layer in the first region.

16. The ray detector according to claim 15, further comprising a dielectric layer covering an exposed surface of the insulating layer and the third transistor electrode.

17. The ray detector according to claim 16, further comprising leads, which penetrate through the dielectric layer and the insulating layer along a thickness direction of the dielectric layer and the insulating layer, and are respectively electrically connected to the first diode electrode and the second diode electrode.

18. The ray detector according claim 9, wherein the substrate comprises one of a glass-based substrate and a silicon-based substrate.

19. An electronic device, comprising the ray detector according to claim 9.

20. The ray detector according to claim 17, further comprising an anode layer, wherein the anode layer comprises a first lead electrode and a second lead electrode, and the leads are electrically connected to the first lead electrode and the second lead electrode, respectively.
